(19) United States
(12) Patent Application Publication
(10) Pub. No.: US 2006/0202299 A1
(43) Pub. Date: Sep. 14, 2006

(54) Semiconductor devices integrating high-voltage and low-voltage field effect transistors on the same wafer

(75) Inventor: Mourad Chertouk, Hsinchu Shien (TW)

Correspondence Address: LOWE HAUPTMAN BERNER, LLP, 1700 DIAGONAL ROAD, SUITE 300, ALEXANDRIA, VA, 22314, US

(73) Assignee: WIN Semiconductors Corp.

(21) Appl. No.: 11/078,408

(22) Filed: Mar. 14, 2005

(51) Int. Cl. H01L 29/00

(52) U.S. Cl. 257/500

(57) ABSTRACT

A field effect transistor (FET) with novel field-plate structure relates to a Schottky gate FET structure with field plate thereon for high voltage operations. The structure and fabrication processes thereof not only provide a reliable way to produce high-voltage FETs, but also allow the integration of conventional low-voltage FETs on the same wafer.

### FIELD OF THE INVENTION

The present invention generally relates to a semiconductor device. More specifically, the present invention relates to a field-effect transistor (FETs) having a novel field plate structure thereon, which involves fabrication processes that are fully compatible with those of conventional low-voltage FETs and are capable of integrating high-voltage and low-voltage FETs on the same wafer.

### BACKGROUND OF THE INVENTION

Compound semiconductor field effect transistor (FET) operating at microwave frequency is the key component used in wireless and satellite communications. Well known devices for such applications include GaAs metal-semiconductor FETs (MESFETs) and Heterostructure FETs, such as AlGaAs/GaAs based high electron mobility transistor (HEMT) as well as pseudomorphic HEMT (PHEMT) with strained channel layer therein.

For a conventional FET, it generally comprises a Schottky gate electrode thereon and a source and a drain electrodes being ohmic contacted to a channel layer therein. When a voltage is applied to the Schottky gate electrode, the current flow from the drain to the source electrodes through the channel layer will be modified due to the variation of carrier density therein caused by the applied gate voltage. As a result, applying a modulation voltage or a control voltage to the gate electrode enables a FET functioning as an amplifier or a switch.

For a power FET amplifier, the Schottky gate junction is usually biased at high voltages in order to achieve high output power. In this circumstance, a region of huge electric field will be formed in the channel underneath the gate edge on the drain side. Such a large electric field will lead to an avalanche breakdown in the channel region between the gate and the drain electrodes, resulting in a deterioration of high frequency performance.

To achieve high output power and/or high-voltage operations, the breakdown voltage between the gate and the drain electrodes has to be increased. A straightforward method to increase the breakdown voltage of a Schottky gate FET is to increase the distance between the gate and the drain electrodes so that both the electric field strength and the leakage current can be effectively reduced. However, larger gate-drain distance will also lead to larger sheet resistance, which in effect reduces the maximum output current and hence the maximum output power that could be extracting from the device.

A more commonly used method to increase the operation voltage of a Schottky gate FET is the use of a field plate structure. FIG. 1 shows a cross-section view of a typical Schottky gate FET with field-plate gate structure. It generally comprises a semiconductor substrate 11, a channel layer thereon 12. A contact layer generally made of a heavily-doped semiconductor layer formed a source region 13 with a source electrode 14 deposited thereon, and a drain region 15 with a drain electrode 16 thereon. Between the source and the drain region, the contact layer is removed, either by wet chemical etching or dry etching, forming a recess region. On the recess region of the contact layer, a dielectric film 17 is formed. The dielectric film 17 may be a silicon nitride film, a silicon dioxide film, or other dielectric materials that can used for surface passivation and electrical isolations. On the dielectric film 17, a gate recess opening is formed, commonly by using plasma etching processes. A field plate-gate 18 is then form on the dielectric film and making a Schottky contact with the channel layer 12 via the gate recess opening. The field-plate gate 18 in FIG. 1 is in an asymmetric shape, or so-called Γ-gate structure, with a field plate extending from the gate recess opening toward the drain electrode. The field plate is isolated from the channel by the dielectric film 17, so that the electric field centralizing at the gate edge on the drain side can be effectively suppressed.

The field-plate approach has been widely used in Si metal-oxide-semiconductor (MOS) FETs to achieve higher breakdown voltage. For GaAs-based power FETs, it has also been demonstrated that excellent performance in both breakdown voltage and output power by using dielectric-assisted field-plate gate structure as shown in FIG. 1. For this approach, it is worth mentioning that the Γ gate electrode has to be formed after the deposition of dielectric film and the plasma etching of gate recess opening. However, it is difficult to control plasma damage during the gate recess undercut, which inevitably degrades the interface property of the gate Schottky contact as well as the surface of the unpassivated region. Consequently, the device reliability suffers frequently.

Another drawback of the Γ gate approach is that it is very difficult to integrate the high-voltage FET with conventional low-voltage FET on the same wafer. Some applications like CATV or broadband amplifier with high dynamic range need both low-voltage (high gain) devices for control circuitry at gain stage and high-voltage FETs for the amplifier at the output stage. From the aspect of device integration, it is very important to develop a novel field-plate structure, which involves fabrication processes that are fully compatible with those of conventional low-voltage FETs and are capable of integrating high-voltage and low-voltage FETs on the same wafer.

### SUMMARY OF THE INVENTION

Accordingly, it is an object of the present invention to provide a novel field-plate structure for a Schottky gate FET, which not only makes the device to have a high breakdown voltage with a high confidence level of reliability, but also allows the integration of high-voltage FET with conventional low-voltage FETs on the same wafer.

It is also an object of the present invention to provide a novel field-plate structure for a Schottky gate FET involving fabrication processes that can eliminate surface damages of unpassivated region and avoid degradation of the interface property of gate contacts during plasma etching of dielectric film for Schottky gate formation.

Another object of the present invention is to provide a novel field-plate structure for a Schottky gate FET, which can be integrated with a conventional low-voltage FET without field plate on the same wafer.

It is still an object of the present invention to provide a novel field-plate structure for a Schottky gate FET involving fabrication processes that are fully compatible with those for low-voltage FETs without field plates for device system integration.

In order to achieve the above-mentioned objects, the field effect transistors of the present invention comprise a semiconductor substrate and a channel layer thereon. A contact layer is formed a source region, a drain region with a distance is apart from said source region and a recess region is formed by removing part of said contact layer between said source and said drain regions. A source electrode is formed on said source region, making an ohmic contact with said contact layer and electrically coupled to said channel layer underneath. A drain electrode is formed on said drain region, making an ohmic contact with said contact layer and electrically coupled to said channel layer underneath. A gate electrode has a finger shape, being formed on said recess region of said contact layer, and forming a Schottky contact with said channel layer underneath. A dielectric film is overlaying the region between said source electrode and drain electrode, including said gate electrode finger. A separated field plate is disposed on said dielectric film between said gate electrode finger and drain electrode, wherein said filed plate is electrically isolated from said gate electrode and said drain electrode is electrically connected to said source electrode via a contact hole on said dielectric film.

The semiconductor devices of the present invention comprise at least two field-effect transistors fabricated on the same wafer, wherein one of the field-effect transistor is designed for high-voltage and the other is designed for low-voltage operation.

### BRIEF DESCRIPTION OF DRAWINGS

FIG. 1 is a cross-section view of a typical Schottky gate FET with Γ-shape field-plate gate structure.

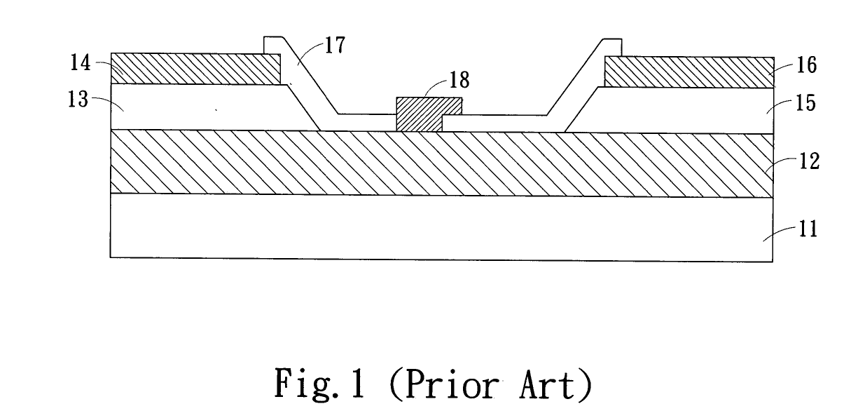

FIG. 2 is a cross-section view of the Schottky gate FET structure of the present invention having a separated field plate thereon being connecting to the source electrode.

FIG. 3 shows a cross-section view of the Schottky gate FET structure with a separated field plate thereon of the present invention being integrated with a conventional low-voltage FET without field plate on the same wafer.

### DETAILED DESCRIPTION OF THE INVENTION

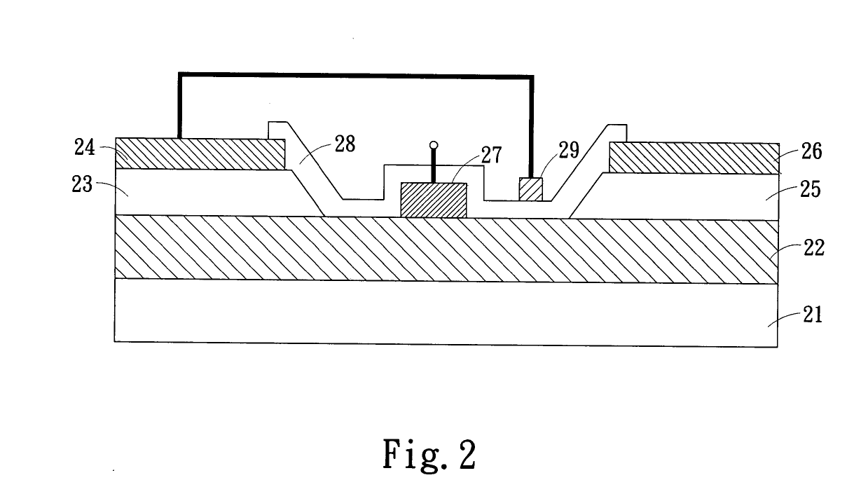

FIG. 2 is a cross-section view of the Schottky gate FET structure of the present invention having a separated field plate thereon. The semiconductor layer structure in FIG. 2 generally comprises a substrate 21 and a channel layer 22 thereon, whereon a contact layer is formed. The contact layer has a source region 23, a drain region 25 with a distance apart from the source region 23 and a recess region being formed by removing part of the contact layer between the source region 23 and the drain region 25. A source electrode 24 and a drain electrode 26 are formed on the source region 23 and the drain region 25, respectively. Both the source electrode 24 and the drain electrode 26 make an ohmic contact with the contact layer, and being electrically coupled to the channel layer 22 underneath. On the recess region of the contact layer, a gate electrode 27, having a finger shape, is formed and making a Schottky contact with the channel layer 22 underneath. After the formation of the source, drain and gate electrodes, a dielectric film 28 is overlaid for surface passivation, which covers the recess region of the contact layer, including the gate electrode finger 27 thereon. On the dielectric film 28, an electrically conductive field plate 29 is disposed between, and electrically isolated from, the gate electrode 27 and the drain electrode 26. The field plate 29 is electrically connected to the source electrode 24, via a contact hole on the dielectric film being etched down to the source electrode 24 before overlaying the field plate 29 thereon. (Note to WIN: please check the underline sentence, because I am not sure whether this process is correct.)

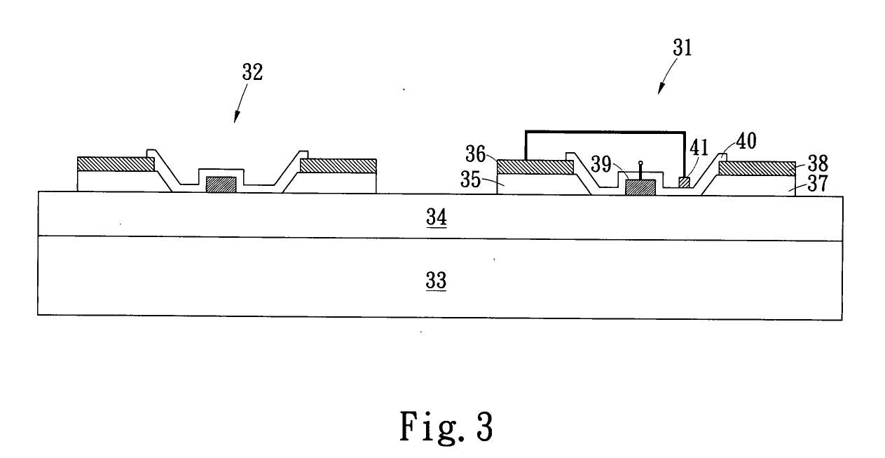

The advantage of the approach disclosed in the present invention is multifold, as compared with the conventional Schottky gate FET with Γ gate thereon. First, the plasma damages resulted from plasma etching of dielectrics on the active region are eliminated because no plasma etching is need for gate formation. Second, the unpassivated areas created during gate recess next to gates are eliminated because passivation is performed after gate etch and metallization. Consequently, both performance and reliability are improved. Third, since the field plate 29 is electrically connecting to the source electrode 24 instead of gate electrode, the parasitic capacitance caused by the field plate can be reduced. For a conventional Γ-gate FET, the field plate effectively increases the gate capacitance, resulting in a deterioration of high frequency performance. Finally, the separated field-plate structure as shown in FIG. 2 also provide a possible way to integrate a high-voltage FET with a conventional low-voltage FET on the same wafer, since the fabrication processes involved in each are fully compatible. FIG. 3 shows an example of the present invention, which illustrates the integration of a high-voltage FET with a separated field plate thereon and a low-voltage FET without field plate on the same wafer. Although this example only illustrates two FETs on a wafer, it can obviously be extend to more FETs, forming a practical integrated circuit for real applications and mass production. In FIG. 3, it consists of a high voltage FET 31 and a low-voltage FET 32. Both the FETs comprise a same substrate 33, a same channel layer 34 thereon, and a same contact layer. The structure of the high-voltage FET 31 is the same as that shown in FIG. 2, having a source region 35 and a source electrode 36 thereon, a drain region 37 and a drain electrode 38 thereon, a gate electrode 39 making Schottky contact to the channel layer in the recess region, and a dielectric film 40 thereon for device passivation. A field plate 41 is disposed on the dielectric film between the gate electrode 39 and the drain electrode 38. The field plate 41 is electrically isolated from both the gate electrode 39 and the drain electrode 38, and electrically connected to the source electrode 36 for eliminating the field-plate induced parasitic capacitance. For the low-voltage FET 32, it generally comprises the source, drain, and gate structures that are the same as those on the high-voltage FET 31 except the absence of field plate structure. Therefore, the processes involved for fabricating both FETs are fully compatible. This novel structure provides a promising and economical way to fabricate integrated circuit containing both high-voltage and low-voltage FETs.

What is claimed is:

1. A semiconductor device, comprising at least two field-effect transistors fabricated on the same wafer, wherein one of said field-effect transistor is designed for high-voltage and the other one is designed for low-voltage operation.

2. The semiconductor device as described in claim 1, wherein both of said field-effect transistors comprise:
a same semiconductor substrate and a same channel layer thereon;
a contact layer forming a source region, a drain region with a distance apart from said source region and a recess region being formed by removing part of said contact layer between said source and said drain regions;
a source electrode being formed on said source region, making an ohmic contact with said contact layer and being electrically coupled to said channel layer underneath;
a drain electrode being formed on said drain region, making an ohmic contact with said contact layer and being electrically coupled to said channel layer underneath;
a gate electrode having a finger shape, being formed on said recess region of said contact layer, and forming a Schottky contact with said channel layer underneath; and
a dielectric film overlaying the region between said source electrode and drain electrode, including said gate electrode finger.

3. The semiconductor device as described in claim 2, wherein one of said field-effect transistors being specifically designed for high-voltage operation further comprises a field plate disposing on said dielectric film and between said gate finger electrode and said drain electrode.

4. The semiconductor device as described in claim 3, wherein said field plate is electrically isolated from said gate electrode and said drain electrode and is further electrically connected to said source electrode.

5. The semiconductor device as described in claim 2, wherein said semiconductor substrate is a kind of III-V materials.

6. The semiconductor device as described in claim 2, wherein said channel layer of both field-effect transistors is conductive, and the conductive carriers (electrons or holes) therein are provided either by direct doping in said channel or by modulation doping.

7. The semiconductor device as described in claim 2, wherein said dielectric film on both field-effect transistors is made of silicon nitride, silicon dioxide, silicon oxynitride or other insulating dielectric materials.

8. The semiconductor device as described in claim 2, wherein said dielectric film on both field-effect transistors is set such that the electric field strength below said field plate can modify the electric field distribution in said channel layer at the gate edge on the drain side and prevent junction breakdown between said gate and said drain electrodes of the field-effect transistor being specifically designed for high-voltage operations.

9. A field effect transistor, comprising:
a semiconductor substrate and a channel layer thereon;
a contact layer forming a source region, a drain region with a distance apart from said source region and a recess region being formed by removing part of said contact layer between said source and said drain regions;
a source electrode being formed on said source region, making an ohmic contact with said contact layer and being electrically coupled to said channel layer underneath;
a drain electrode being formed on said drain region, making an ohmic contact with said contact layer and being electrically coupled to said channel layer underneath;
a gate electrode having a finger shape, being formed on said recess region of said contact layer, and forming a Schottky contact with said channel layer underneath;
a dielectric film overlaying the region between said source electrode and drain electrode, including said gate electrode finger; and
a separated field plate being disposed on said dielectric film between said gate electrode finger and drain electrode, wherein said field plate is electrically isolated from said gate electrode and said drain electrode is electrically connected to said source electrode via a contact hole on said dielectric film.

10. The field effect transistor as described in claim 9, wherein the thickness of said dielectric film under said field plate is set such that the electric field strength right underneath can modify the electric field distribution in said channel layer at the gate edge on the drain side and prevent junction breakdown between said gate and said drain electrodes under high-voltage operations.

11. The field effect transistor as described in claim 9, wherein said semiconductor substrate is a kind of III-V materials.

12. The field effect transistor as described in claim 9, wherein said channel layer is conductive, and the conductive carriers (electrons or holes) therein are provided either by direct doping in said channel or by modulation doping.

13. The field effect transistor as described in claim 9, wherein said dielectric film is made of silicon nitride, silicon dioxide, silicon oxynitride or other insulating dielectric materials.
